(19) United States
(12) Patent Application Publication
(10) Pub. No.: US 2026/0293559 A1
(43) Pub. Date: Sep. 24, 2026

(54) METHODS FOR ETCHING SEMICONDUCTOR DEVICES

(71) Applicant: Tokyo Electron Limited, Tokyo (JP)

(72) Inventor: Alec Dorfner, Albany, NY (US)

(21) Appl. No.: 19/083,225

(22) Filed: Mar. 18, 2025

(51) Int. Cl. H01L 21/311

(52) U.S. Cl. CPC H10P 50/73; H10P 50/283

(57) ABSTRACT

A method is provided for etching a substrate. The method includes transferring a substrate into a process chamber, where the substrate includes a metal-containing layer disposed over a layer to-be-patterned, and a patterned metal oxide resist layer disposed over the metal-containing layer. A gas mixture including fluorocarbon and SiCl₄ is flowed into the process chamber. A plasma is generated from the gas mixture in the process chamber by applying RF power. The substrate is exposed to the plasma, which transfers a pattern of the patterned metal oxide resist layer to the metal-containing layer to form a patterned metal-containing layer.

### TECHNICAL FIELD

The present invention relates generally to the field of semiconductor manufacturing and semiconductor devices, and, in particular embodiments, to methods of etching semiconductor devices.

### BACKGROUND

Photolithography is commonly used to pattern thin films during semiconductor device processing, where photons are emitted from a light source onto a photosensitive photoresist to initiate a chemical reaction in the photoresist. Thereafter, the photoresist is developed and exposed or unexposed portions of the photoresist are removed to form a pattern or a mask.

Scaling of semiconductor devices has enabled significant technological advances, including advanced lithographic techniques such as immersion lithography. Extreme ultraviolet (EUV) radiation can be used for providing improved pattern resolution in advanced integrated circuits where reduction in feature sizes is required. Common EUV photoresists are polymer-based chemically amplified resists (CARs) that are deposited on substrates using liquid-based spin-on techniques that consume a significant number of complex precursors. Recently, inorganic-based resists such as metal oxide resist (MOR) have received interest as they may be patterned using EUV radiation and can offer the high etch resistance and etch selectivity needed for semiconductor manufacturing.

### SUMMARY

In accordance with one aspect of the present invention, a method is provided for etching a substrate. The method includes transferring a substrate into a process chamber, where the substrate includes a metal-containing layer disposed over a layer to-be-patterned, and a patterned metal oxide resist layer disposed over the metal-containing layer. A gas mixture including fluorocarbon and SiCl₄ is flowed into the process chamber. A plasma is generated from the gas mixture in the process chamber by applying RF power. The substrate is exposed to the plasma to transfer a pattern of the patterned metal oxide resist layer to the metal-containing layer, forming a patterned metal-containing layer.

In accordance with another aspect of the present invention, a method is provided for etching a substrate. After loading the substrate into a process chamber, a gas mixture including fluorocarbon and BCl₃ is flowed into the process chamber. The substrate includes a metal-containing layer disposed over a layer to-be-patterned, and a patterned metal oxide resist layer disposed over the metal-containing layer. A plasma is generated in the process chamber from the gas mixture by applying RF power to an electrode of the process chamber. The substrate is exposed to the plasma to transfer a pattern of the patterned metal oxide resist layer to the metal-containing layer.

In accordance with yet another aspect of the present invention, a method is provided for etching a substrate. The method includes loading a substrate into a process chamber, where the substrate includes a metal oxide resist layer disposed over a metal-containing layer, and the metal-containing layer is disposed over a layer to-be-patterned. A pattern is etched through the metal oxide resist layer to form a patterned metal oxide resist layer. A gas mixture including CF₄ and SiCl₄, or CF₄ and BCl₃, or C₄F₆ and SiCl₄ is flowed into the process chamber. A plasma is generated from the gas mixture in the process chamber. The pattern of the patterned metal oxide resist layer is transferred to the metal-containing layer and the layer to-be-patterned.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1H illustrate cross-sectional views of an example process for etching a substrate, in accordance with an embodiment;

FIGS. 2A-2D illustrate cross-sectional views of an example process for etching a substrate variation, in accordance with an embodiment;

FIG. 3 illustrates a process flow of etching metal-containing layer using metal oxide resist as etch mask, in accordance with an embodiment;

FIG. 4 illustrates a variation of process flow of etching metal-containing layer using metal oxide resist as etch mask, in accordance with an embodiment;

FIGS. 5A-5B shows Gibbs free energy analyses during an etching process under different chemistry conditions, in accordance with an embodiment;

FIG. 6 illustrates an example process system to etch a substrate, in accordance with an embodiment; and

FIGS. 7A-7F show X-ray photoelectron spectroscopy (XPS) spectra of metal-containing layer and metal oxide resist (MOR) layer during etching under different chemistry conditions, in accordance with an embodiment.

### DETAILED DESCRIPTION OF ILLUSTRATIVE EMBODIMENTS

In various embodiments, a metal-containing layer, such as titanium (Ti), positioned beneath metal oxide resist (MOR) enhances extreme ultraviolet (EUV) lithography performance by reducing the required exposure dose while maintaining target critical dimensions. This reduction in dose-to-size ratio improves EUV scanner throughput, enabling faster wafer processing times and enhanced production efficiency. However, conventional chlorine-based etch chemistry demonstrates poor selectivity between titanium (Ti) and MOR.

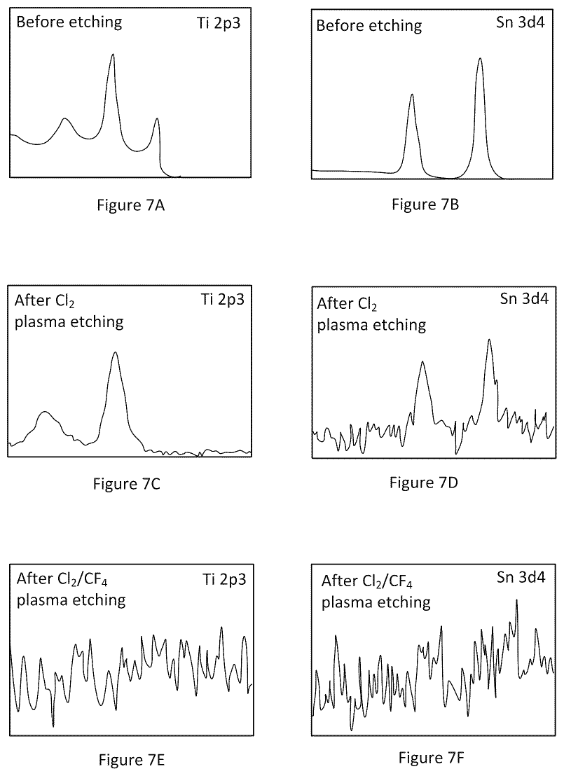

X-ray photoelectron spectroscopy (XPS) analyses shown in FIGS. 7A-7F characterize surface chemistry changes during plasma etching of a substrate having a patterned tin-containing MOR layer formed on a titanium layer. FIGS. 7A and 7B show baseline Ti 2p3 and Sn 3d4 peak intensities prior to plasma exposure, exhibiting well-defined spectral features. FIGS. 7C and 7D show the Ti 2p3 and Sn 3d4 peak intensities after Cl₂ plasma etching, where the Ti 2p3 signal maintains defined peaks while showing reduced intensity, whereas the Sn3d4 signal exhibits increased noise and peak degradation. FIGS. 7E and 7F show the Ti 2p3 and Sn 3d4 peak intensities after Cl₂/CF₄ plasmas etching, both Ti 2p3 and Sn 3d4 signals exhibit substantial peak degradation with increased baseline noise, indicating etching of both materials. The XPS data illustrate that chlorine-based plasma chemistries may etch both the titanium layer and the tin-containing MOR layer, compromising pattern transfer fidelity.

In one or more embodiments, etch chemistries incorporating fluorocarbon/SiCl₄, or fluorocarbon/BCl₃ combinations provide enhanced selectivity between titanium and MOR materials. The selective nature of these chemistries may be fundamentally supported by thermodynamic principles, specifically the Gibbs free energy differences between titanium oxide and tin oxide reactions. The reactions with titanium oxide exhibit more negative Gibbs free energy values compared to corresponding tin oxide reactions when using fluorocarbon/SiCl₄, or fluorocarbon/BCl₃ combinations. These energy differences indicate titanium oxide etching is thermodynamically favorable over tin oxide etching, resulting in improved etch selectivity.

In various embodiments, these selective etch chemistries enable precise pattern transfer while preserving MOR integrity. The thermodynamically-driven selectivity provides consistent and reliable pattern transfer operations while maintaining critical dimensions and underlying material structure. This improved selectivity, compared to traditional chlorine-based approaches, enables efficient integration of titanium underlayers in advanced EUV lithography processes, combining the benefits of reduced EUV dose requirements with reliable pattern transfer capabilities.

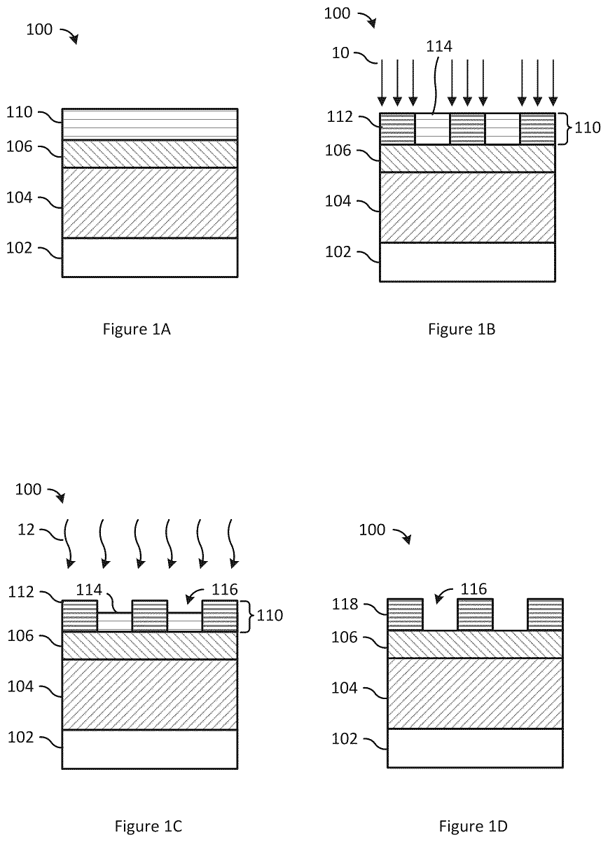

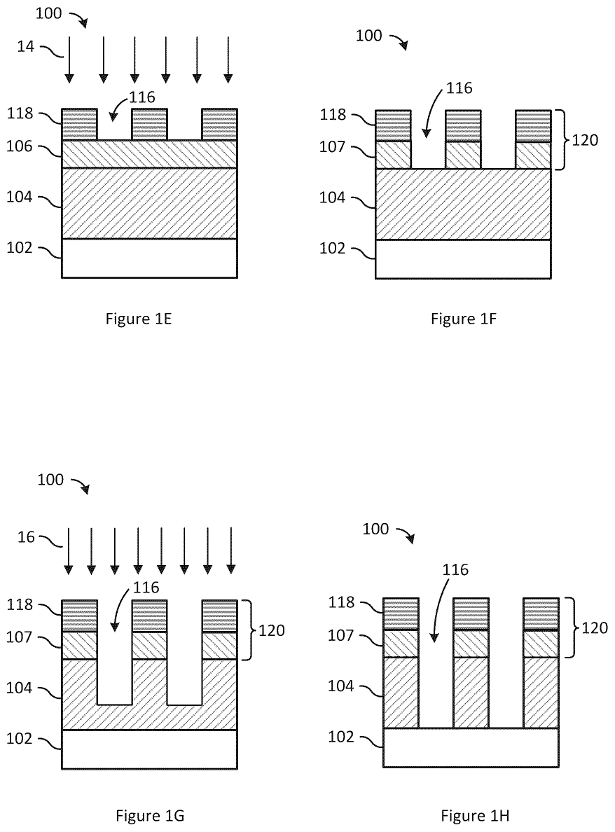

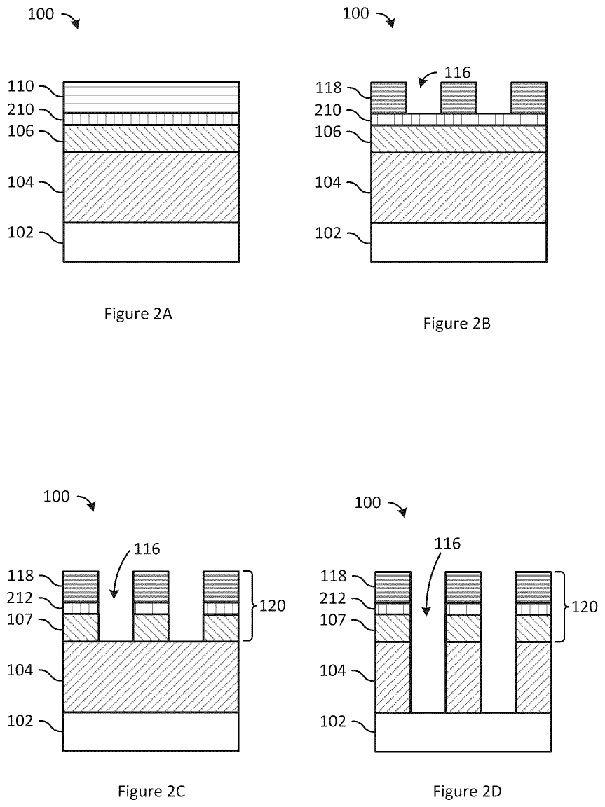

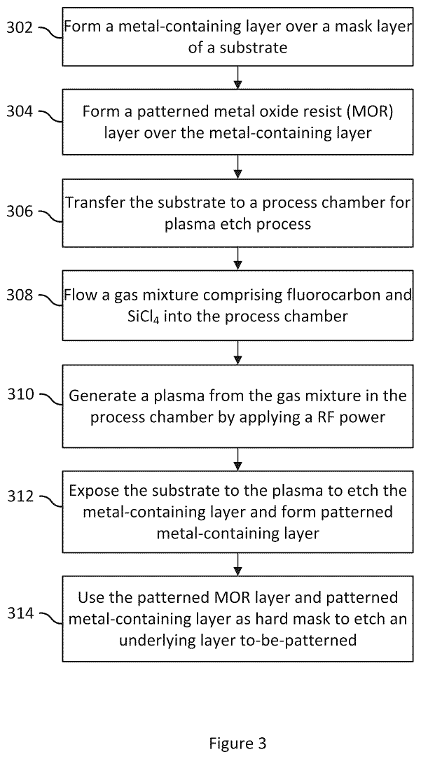

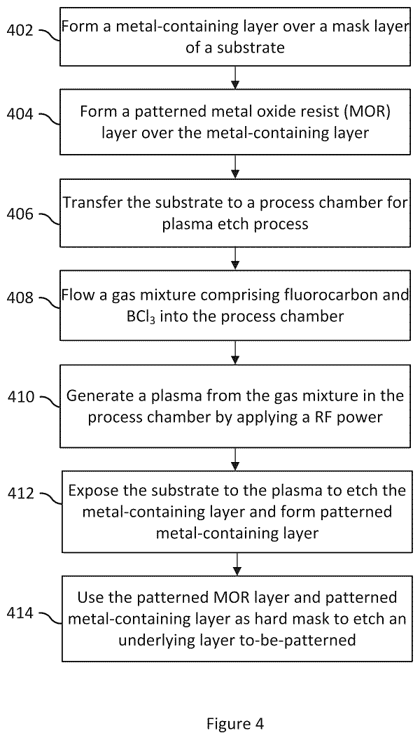

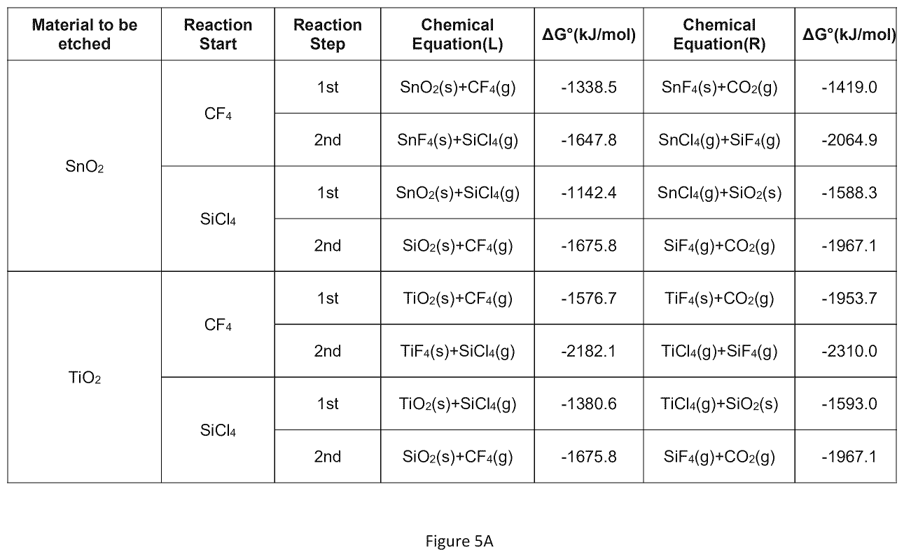

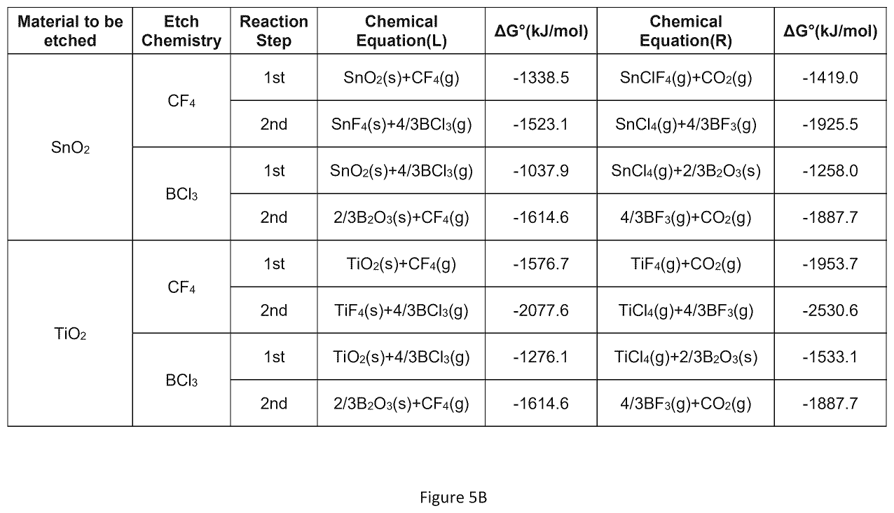

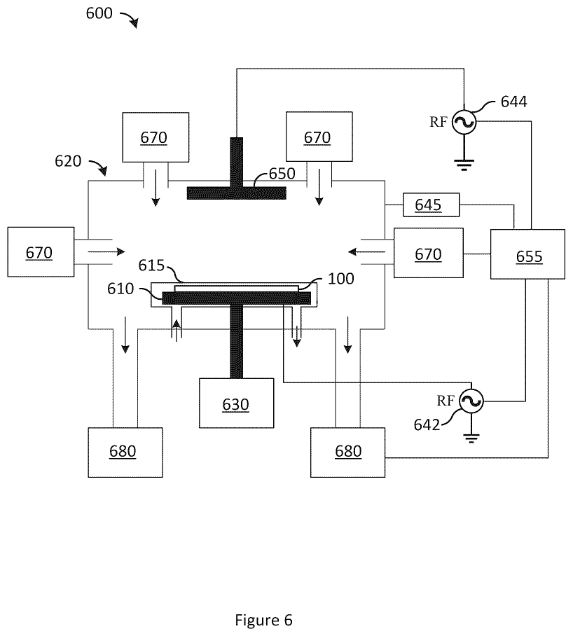

Embodiments of the disclosure are described in the context of the accompanying drawings. An embodiment of an example fabrication process including etching a MOR layer is described using FIGS. 1A-1H. FIGS. 2A-2D illustrate an embodiment variation of processing a substrate variation. Embodiments of methods for etching a substrate with etch chemistries of fluorocarbon/SiCl₄, or fluorocarbon/BCl₃ combinations are described using FIGS. 3-4. Embodiments of Gibbs free energies during etching a substrate are shown in FIGS. 5A-5B. Embodiment of a system to etch the substrate is illustrated in FIG. 6. Embodiments of exemplary data of conventional chlorine-based etch chemistries are shown in FIGS. 7A-7F.

FIGS. 1A-1H illustrate steps of an example method to process a substrate 100 in a process chamber, in accordance with an embodiment.

FIG. 1A illustrates a cross-sectional view of the substrate 100 to be processed. In various embodiments, the substrate 100 may comprise a layer to-be-patterned 104 disposed over a substrate layer 102. A metal-containing layer 106 may be disposed over the layer to-be-patterned 104. A metal oxide resist (MOR) layer 110 may be disposed over the metal-containing layer 106. As illustrated in FIG. 2A, in some embodiments, the substrate 100 may further comprise a metal oxide layer 210 disposed between the metal-containing layer 106 and the MOR layer 110.

In one or more embodiments, the substrate layer 102 may be a silicon wafer, or a silicon-on-insulator (SOI) wafer. In certain embodiments, the substrate layer 102 may comprise silicon germanium, silicon carbide, gallium arsenide, gallium nitride, or other compound semiconductors. In other embodiments, the substrate layer 102 may comprise heterogeneous layers such as silicon germanium on silicon, gallium nitride on silicon, silicon carbon on silicon, as well layers of silicon on a silicon or SOI substrate. In various embodiments, the substrate layer 102 may be patterned or embedded in other components of the semiconductor device.

In various embodiments, although not illustrated, the substrate layer 102 may further comprise various layers useful for semiconductor device fabrication, which may be collectively regarded as a part of the substrate layer 102 in this disclosure. For example, in certain embodiments, over the substrate layer 102, there may be a dielectric layer comprising a silicon-based dielectric material with a low dielectric constant (i.e., low-k value) such as organosilicate glass (SiCOH), dense SiCOH, porous SiCOH, and other porous dielectric materials.

The layer to-be-patterned 104 represents a layer that will be subsequently patterned. In one or more embodiments, the layer to-be-patterned 104 may comprise silicon, silicon oxide, silicon nitride, silicon carbonitride (SiCN), silicon oxycarbide (SiOC), organic materials, non-organic materials, spin-on carbon, amorphous carbon, a combination thereof, or the like. In an embodiment, the layer to-be-patterned 104 may be a silicon bottom anti-reflective coating (Si-BARC), which can enhance the precision of subsequent patterning steps. Further, the layer to-be-patterned 104 may be a stacked hard mask comprising, for example, two or more layers using two different materials. In some of such embodiments, the first hard mask of the layer to-be-patterned 104 may comprise a metal-based layer such as titanium nitride, titanium, tantalum nitride, tantalum, tungsten-based compounds, ruthenium-based compounds, or aluminum based compounds, and the second hard mask material of the layer to-be-patterned 104 may comprise a dielectric layer such as silicon oxide, silicon nitride, SiCN, SiOC, silicon oxynitride, or silicon carbide.

The layer to-be-patterned 104 may be deposited using suitable deposition techniques such as vapor deposition including chemical vapor deposition (CVD), physical vapor deposition (PVD), as well as other plasma processes such as plasma enhanced CVD (PECVD), sputtering, and other processes including wet processes. The layer to-be-patterned 104 may have a thickness of about 5 nm to about 50 nm in various embodiments.

In various embodiments, the MOR layer 110 may comprise tin (Sn), antimony (Sb), hafnium (Hf), zirconium (Zr), zinc (Zn), the like, or a combination thereof. In certain embodiments, the MOR layer 110 may comprise a metal oxide, a metal alkoxide, or a methacrylate (MAA) of Sn, Sb, Hf, Zr, Zn, or the like, such as ZrMAA, SbMAA, SbMAA: F, HfMAA, ZnMAA, and ZnMAA: F. In certain embodiments, the MOR layer 110 may be a network of metal oxide comprising a metal alkoxide, metal alkenoxide, metal aryloxide, or metal carboxylate group. These groups bonded to the metal are generally represented by chemical formulas, —OR, —OR′, —OAr, and —OOCR, respectively, where R is an alkyl group, R′ is an alkene group, and Ar is an aryl group. In various embodiments, the MOR layer 110 is a polymeric film, and may not have a highly ordered structure such as crystalline. The number of the above functional groups bonded to the metal atom may differ for each metal atom, ranging between 1 and 4. The deposition of the MOR layer 110 may be performed by a dry or wet process. In various embodiments, the MOR layer 110 may be deposited by vapor deposition, for example, chemical vapor deposition (CVD), plasma-enhanced CVD (PECVD), atomic layer deposition (ALD), or plasma-enhanced ALD (PEALD).

In certain embodiments, the deposition process for the MOR layer 110 may comprise exposing the substrate 100 to two precursors in a process chamber: a metal-containing precursor (e.g., a tin-containing precursor) and an oxygen-containing precursor. The exposures to these precursors may be performed stepwise or simultaneously. In various embodiments, the deposition process may be an ALD or pseudo-ALD process and comprise two or more exposing steps. For example, the deposition process may be performed by first exposing the substrate 100 to the tin-containing precursor that forms an adsorbed layer on the substrate 100 and, thereafter, exposing the substrate 100 to the oxygen-containing precursor gas that reacts with the adsorbed tin-containing precursor. The exposing steps may be repeated one or more times to increase a thickness of the MOR layer 110. In certain embodiments, the exposing steps may be separated temporally or spatially. Temporally separating the exposing steps may be realized by changing the gas composition in a process chamber. On the other hand, spatially separating the exposing steps may be enabled by utilizing multiple spatially segregated sections within the process chamber and transporting the substrate from one section to another. For temporally separating the exposing steps even better, the vapor deposition may further include evacuating, purging, or both evacuating and purging, the process chamber between the exposing steps. These additional steps may be beneficial in ensuring the reaction occurs only on surface and not in the gas phase. The ALD or pseudo-ALD method in accordance with this embodiment may be particularly advantageous in enabling layer-by-layer growth of the MOR layer 110 with a high uniformity.

In another embodiment, instead of the ALD type process, the precursors may be supplied in the process chamber simultaneously to grow the MOR layer 110. Such an embodiment may be advantageous by allowing the continuous growth of the MOR layer 110 in a single step. In this embodiment, the reaction between the precursors may or may not occur in the gas phase as well as on surface.

In other embodiments, the MOR layer 110 may be deposited by liquid deposition using alternate exposures of a tin-containing precursor liquid and an oxygen-containing precursor liquid. The liquid deposition may further include rinsing the substrate with a rinsing solution to remove an excess amount and/or unreacted portion of the precursors between the exposing steps. The rinsing solution may comprise deionized water, common organic solvents such as acetone, propylene glyclol monomethyl ether acteate, 1-Methoxy-2-propanol, methyl isobutyl carbinol, hexane, tert-butanol and isopropanol, or mixtures thereof. In another embodiment, the liquid precursors may be mixed first and the mixture solution may be applied to the substrate to grow the MOR layer 110. In one or more embodiments, one of the precursors may be gaseous and another of the precursors may be liquid, and accordingly two different modes (vapor and liquid) of delivery may be utilized to perform the deposition process.

In various embodiments, after forming the MOR layer 110, an optional post-apply bake may be performed to remove any excess solvents from a wet process, residual volatile byproducts from a dry process, or both.

In various embodiments, the metal-containing layer 106 is positioned beneath the MOR layer 110. The metal-containing layer 106 may enhance EUV lithography performance by reducing the required exposure dose while maintaining target critical dimensions in the MOR layer 110. The reduced dose-to-size ratio could improve throughput in EUV lithography tools, resulting in faster wafer processing times and improved production efficiency.

In various embodiments, the metal-containing layer 106 may comprise titanium-containing materials, hafnium-containing materials, aluminum-containing materials, zirconium-containing materials, or the like. Titanium-containing materials may include elemental titanium, titanium nitride, titanium oxide, or the like. Hafnium-containing materials may include elemental hafnium, hafnium nitride, hafnium oxide, or the like. Aluminum-containing materials may include elemental aluminum, aluminum nitride, aluminum oxide, or the like. Zirconium-containing materials may include elemental zirconium, zirconium nitride, zirconium oxide, or the like. The metal-containing layer 106 may serve as an intermediate layer for pattern transfer.

In various embodiments, the metal-containing layer 106 may have a thickness of 0.5 nm to 20 nm. In various embodiments, the metal-containing layer 106 may be deposited by vapor deposition, for example, physical vapor deposition (PVD), chemical vapor deposition (CVD), plasma-enhanced CVD (PECVD), atomic layer deposition (ALD), or plasma-enhanced ALD (PEALD). The deposition parameters, including power, pressure, and deposition time, are controlled to achieve the desired thickness and film quality.

In one or more embodiments, the metal oxide layer 210 illustrated in FIG. 2A may natively form on the surface of the metal-containing layer 106 upon exposure to ambient conditions. In various embodiments, the metal oxide layer 210 may comprise titanium oxide, hafnium oxide, aluminum oxide, zirconium oxide, or the like. In one embodiment, the metal oxide layer 108 comprising TiOₓ (0<x≤2) may be formed over the metal-containing layer 106 comprising titanium. In various embodiments, the titanium oxide layer 108 may have a thickness of several nanometers and form spontaneously when the surface of the metal-containing layer 106 contacts oxygen in the atmosphere. The native oxide formation may be self-limiting and provide a stable surface for subsequent MOR deposition.

FIG. 1B illustrates a cross-sectional view of the substrate 100 after an exposure to actinic radiation, such as EUV light. In various embodiments, the substrate 100 is exposed to an EUV light pattern 10 generated using a photomask positioned between the MOR layer 110 and an EUV light source (not illustrated). In response to the exposure to the EUV light pattern 10, a photoreaction may occur in exposed regions 112 of the MOR layer 110, while unexposed regions 114 remain unchanged. As a result of the photoreaction, the exposed regions 112 may comprise a cross-linked MOR, which may have material properties substantially different from the unreacted portion of the MOR layer 110 (i.e., the unexposed regions 114). Such a difference in the material properties includes volatility, reactivity, and/or solubility among others, which gives origin to the tonality as a photoresist. In some embodiments, a post-exposure bake may be performed to activate the chemical changes initiated by the exposure.

In FIG. 1C, a developing process on the MOR layer 110 is illustrated. In various embodiments, a developing gas 12 may be flowed into the process chamber to etch the unexposed regions 114. In various embodiments, the developing gas 16 may react with the unexposed regions 114 of the MOR layer 110 to produce volatile byproducts, which then evaporate from the surface of the substrate 100. This recesses the unexposed regions 114 with respect to the exposed regions 112, forming openings 116 in the MOR layer 110. In some embodiments, the developing gas 12 may be an acid (reactive gas) such as an inorganic acid (e.g., hydrogen bromide (HBr), hydrogen chloride (HCl), or the like), an organic acid (e.g., acetic acid, trifluoroacetic acid, hexafluoroacetylacetone, acetylacetone, or the like), a Lewis acid (e.g., boron trichloride (BCl₃), boron tribromide (BBr₃), or the like), or a combination thereof.

FIG. 1D illustrates a cross-sectional view of the substrate 100 after developing the MOR layer 110, in accordance with an embodiment. After the conclusion of the developing process through the developing gas 12, the unexposed regions 114 may been removed. The openings 116 may extend through the MOR layer 110 and portions of the top surface of the metal-containing layer 106 may be exposed through the openings 116. In an alternative embodiment illustrated in FIG. 2B, developing the MOR layer 110 may expose portions of the top surface of the metal oxide layer 108.

In various embodiments, FIG. 1C illustrates the development of MOR layer 110 using a negative-tone resist process, where unexposed regions 114 are removed during development while exposed regions 112 remain to form patterned features. In one or more embodiments, a positive-tone MOR material may alternatively be implemented, wherein the EUV exposure increases solubility of the exposed regions 112. In such positive-tone implementations, the exposed regions 112 are removed during development while unexposed regions 114 remain to form patterned features. The selection between negative-tone and positive-tone MOR materials may be determined based on specific integration requirements, pattern density, and critical dimension targets.

Though FIG. 1C illustrates a gas-based development process using the developing gas 12, the MOR layer 110 may alternatively be developed using a liquid-based approach. In various embodiments, a developing solution may be applied to the substrate 100 to remove portions of the MOR layer 110 according to the exposure pattern. The developing solution may comprise aqueous-based developers, organic-based developers, or combinations thereof. The choice between gas-based and liquid-based development processes may depend on factors such as pattern resolution requirements, process integration constraints, and equipment availability. Both development approaches are capable of achieving the desired pattern transfer while maintaining critical dimension control.

Through the lithography process illustrated in FIGS. 1B and 1C, the MOR layer 110 is modified into a patterned metal oxide resist layer 118 (patterned MOR layer 118). The openings 116 define the areas where subsequent etching or material deposition will occur, effectively creating a mask that will be used to transfer the pattern to the underlying layers. In various embodiments, the width and spacing of the openings 116 may be adjusted to achieve different pattern densities and feature sizes. In some embodiments, the patterned MOR layer 118 may serve as a sacrificial layer in the subsequent steps of the fabrication process. The patterned MOR layer 118 protects certain areas of the underlying metal-containing layer 106 while exposing others, thus enabling selective etching or deposition in the following stages of the patterning process.

In various embodiments, as illustrated in FIG. 1E, a plasma 14 may be generated in the process chamber to selectively etch the metal-containing layer 106 through the openings 116. The plasma chemistry may be optimized to achieve substantially higher etch rates for the metal-containing layer 106 while minimizing erosion of the patterned MOR layer 118, enabling precise pattern transfer.

In one or more embodiments, a gas mixture comprising fluorocarbon and SiCl₄ may be flowed into the process chamber. The gas mixture comprising fluorocarbon and SiCl₄ may also be referred to as fluorocarbon/SiCl₄ combination. In various embodiments, the fluorocarbon may comprise CF₄, C₄F₆, C₄F₈, C₂F₆, C₃F₈, or the like, or combinations thereof. In some embodiments, a flow rate ratio of fluorocarbon to SiCl₄ is between 1:4 and 4:1. Flow ratios outside this range may demonstrate reduced etch selectivity between titanium and tin-containing MOR materials, resulting in pattern degradation. In some embodiments, a sum of flow rates of fluorocarbon and SiCl₄ is between 10 sccm and 250 sccm to maintain plasma stability and ensure consistent etch selectivity. In one embodiment, the fluorocarbon may be CF₄. The flow rates of CF₄ and SiCl₄ may be 20 sccm and 22 sccm, respectively. In another embodiment, the fluorocarbon is C₄F₆, and the flow rates of C₄F₆ and SiCl₄ are 6 sccm and 22 sccm, respectively. In some embodiments, additional process gases comprising nitrogen or argon may be incorporated into the gas mixture to enhance plasma characteristics, improve etch uniformity, and control the etch profile.

In various embodiments, scanning electron microscopy (SEM) analysis shows that optimization of the flow rate ratio and the sum of flow rates of the gas mixture helps improve etch selectivity. In one example, the patterned MOR layer 118 comprises tin and the metal-containing layer 106 comprises titanium. The gas mixture comprises CF₄ and SiCl₄. The flow rate of SiCl₄ is fixed at 22 sccm and the flow rate of CF₄ is varied from 15 sccm to 30 sccm. Cross-sectional and top-down SEM images demonstrate that a flow rate ratio of CF₄ to SiCl₄ at 10/11 achieves optimal pattern transfer, maintaining consistent critical dimensions of the openings 116. When the flow rate ratio is lower or higher than 10/11, there may be degraded pattern quality. Furthermore, reducing the sum of flow rates while maintaining flow rate ratios may result in insufficient etch performance. For example, the flow rate of SiCl₄ reduces from 22 sccm to 11 sccm and the flow rate of CF₄ reduces from 20 sccm to 10 sccm. SEM images show that even though the flow rate ratio is not changed, the reduced sum of flow rates may lead to degraded pattern quality. In another example, the gas mixture is the C₄F₆/SiCl₄ combination. The flow rate of SiCl₄ is fixed at 22 sccm and the flow rate of C₄F₆ is changed from 3 sccm to 9 sccm. SEM images show that a flow rate ratio of C₄F₆ to SiCl₄ at 3/11 achieves optimal pattern transfer, maintaining consistent critical dimensions of the openings 116. When the flow rate ratio is lower or higher than 3/11, there may be degraded pattern quality.

In various embodiments, plasma generated from combination of SiCl₄ and fluorocarbon exhibits high etching selectivity of titanium due to favorable thermodynamics in reaction pathways. As illustrated in FIG. 5A, the etching process may involve multiple reaction steps by converting titanium oxide (TiO₂) and tin oxide (SnO₂) to volatile products (e.g., TiCl₄ and SnCl₄). In various embodiments, when SiCl₄ and CF₄ react with the oxides during etch process, the reaction pathway for TiO₂ etching demonstrates more favorable thermodynamics compared to SnO₂ etching, reflecting from more negative Gibbs free energy. For example, the Gibbs free energy of reaction step between TiO₂ and CF₄ is more negative than that between SnO₂ and CF₄ (e.g., −1338.5 kJ/mol vs −1576.7 kJ/mol). The Gibbs free energy of reaction step between TiO₂ and SiCl₄ is more negative than that between SnO₂ and SiCl₄ (e.g., −1380.6 kJ/mol vs −1142.4 kJ/mol). These more negative Gibbs free energy during reactions indicates thermodynamically favorable reactions for titanium etching with SiCl₄ and CF₄.

In various embodiments, advantages of SiCl₄/CF₄ combination in selective etching the metal-containing layer 106 is supported by comparative SEM analysis with conventional chlorine-based chemistry (e.g., a combination of Cl₂, SiCl₄ and CF₄). Top views of the patterned MOR layer 118 after etch process are analyzed. Line edge roughness (LER), which quantifies the deviation of a single feature edge from an ideal straight line, and Line width roughness (LWR), which measures the variation in feature width along its length, may be used to evaluate etch quality and selectivity.

In one or more embodiments, the SiCl₄/CF₄ combination demonstrates improved edge roughness control over the patterned MOR layer 118, with unbiased LER reducing from 2.580±0.092 nm (chlorine-based chemistry) to 1.988±0.066 nm (SiCl₄/CF₄ combination). Similarly, the unbiased LWR improves from 3.27±0.17 nm (chlorine-based chemistry) to 2.78±0.11 nm (SiCl₄/CF₄ combination). The biased measurements show comparable improvements, with LER decreasing from 2.613±0.090 nm (chlorine-based chemistry) to 2.065±0.063 nm (SiCl₄/CF₄ combination) and LWR from 3.32±0.17 nm (chlorine-based chemistry) to 2.78±0.10 nm (SiCl₄/CF₄ combination). Moreover, SiCl₄/CF₄ combination shows better-controlled mean line critical dimension measurements of the patterned MOR layer 118 (reducing from 15.94±0.11 nm to 12.861±0.071 nm), demonstrating that the SiCl₄/CF₄ combination provides improved pattern transfer fidelity and etch selectivity compared to conventional chlorine-based processes.

In one or more embodiments, the gas mixture used to generate the plasma 14 may comprise fluorocarbon and BCl₃. The gas mixture comprising fluorocarbon and BCl₃ may also be referred to as fluorocarbon/BCl₃ combination. In various embodiments, the fluorocarbon may comprise CF₄, C₄F₆, C₄F₈, C₂F₆, C₃F₈, or the like, or combinations thereof. In one or more embodiments, a flow rate ratio of fluorocarbon to BCl₃ may be controlled between 1:4 and 4:1 to achieve optimal selectivity. In some embodiments, a sum of flow rates of fluorocarbon and BCl₃ may be between 10 sccm to 250 sccm to maintain plasma stability and ensure consistent etch selectivity. In one embodiment, the fluorocarbon may be CF₄. The flow rates of CF₄ and BCl₃ may be 25 sccm and 33 sccm, respectively. In some embodiments, additional process gases comprising nitrogen or argon may be incorporated into the gas mixture to enhance plasma characteristics, improve etch uniformity, and control the etch profile.

In various embodiments, SEM analysis shows that optimization of the flow rate ratio and the sum of flow rates of the gas mixture comprising fluorocarbon and BCl₃ helps improve etch selectivity. In one example, the patterned MOR layer 118 comprises tin and the metal-containing layer 106 comprises titanium. Three flow rates of CF₄ and BCl₃ in the gas mixture are tested, i.e., BCl₃ at 133 sccm with CF₄ at 100 sccm, BCl₃ at 33 sccm with CF₄ at 25 sccm, BCl₃ at 16 sccm with CF₄ at 12 sccm. Cross-sectional and top-down SEM images demonstrate that the moderate flow rates (BCl₃ at 33 sccm with CF₄ at 25 sccm) achieves optimal pattern transfer, maintaining consistent critical dimensions of the openings 116. When the flow rates are too high (BCl₃ at 133 sccm with CF₄ at 100 sccm) or too low (BCl₃ at 16 sccm with CF₄ at 12 sccm), there may be degraded etch selectivity and pattern quality.

In various embodiments, similar to fluorocarbon/SiCl₄ combination, plasma generated from fluorocarbon/BCl₃ combination may exhibit high etching selectivity of titanium due to favorable thermodynamics in reaction pathways. As illustrated in FIG. 5B, the etching process may also involve multiple reaction steps by converting titanium oxide (TiO₂) and tin oxide (SnO₂) to volatile products (e.g., TiCl₄ and SnCl₄). In various embodiments, when BCl₃ and CF₄ react with the oxides during etch process, the reaction pathway for TiO₂ etching demonstrates more favorable thermodynamics compared to SnO₂ etching, reflecting from more negative Gibbs free energy. For example, the Gibbs free energy of reaction step between TiO₂ and BCl₃ is more negative than that between SnO₂ and BCl₃ (e.g., −1276.1 kJ/mol vs −1037.9 kJ/mol). These more negative Gibbs free energy during reactions indicates thermodynamically favorable reactions for titanium etching with BCl₃ and CF₄.

The thermodynamic data in FIGS. 5A and 5B support the strategic selection of the fluorocarbon/SiCl₄ combination or fluorocarbon/BCl₃ combination to enable selective removal of titanium while preserving the MOR pattern integrity. These combinations may provide superior performance than conventional chlorine-based plasmas in selective etching of titanium. Conventional chlorine-based plasma may create similar reaction pathways and Gibbs free energy changes for both titanium and tin-containing materials, leading to poor selectivity. The fluorocarbon/SiCl₄ combination or fluorocarbon/BCl₃ combination may leverage the significant differences in Gibbs free energy changes between TiO₂ and SnO₂ reactions for higher selectivity.

In various embodiments, the plasma 14 may be generated from the gas mixture by applying a RF source power (or a high frequency power) to an electrode in the process chamber, wherein the gas mixture may comprise fluorocarbon/BCl₃ combination or fluorocarbon/SiCl₄ combination. In some embodiments, the applied RF power may range from 150 W to 1500 W, with the specific power level selected based on desired etch rates and selectivity requirements. In one or more embodiments, a RF bias power (or a low frequency power) may be applied to the substrate 100 to control plasma reaction with the substrate. The bias RF power may be between 100 W to 500 W. In some embodiments, the pressure of the process chamber may be maintained between 10 mTorr to 300 mTorr to ensure uniform plasma distribution. In some embodiments, the temperature of the substrate 100 may be maintained between 10° C. to 90° C. to obtain optimized reaction kinetics and prevent undesired thermal effects.

In various embodiments, SEM analysis demonstrates the importance of optimizing both RF source power and RF bias power to achieve optimal etch selectivity and pattern integrity. In one embodiment, the patterned MOR layer 118 comprises tin and the metal-containing layer 106 comprises titanium. The gas mixture comprises CF₄ at a flow rate of 20 sccm and SiCl₄ at a flow rate of 22 sccm. When the etch process applies 700 W RF source power and 400 W RF bias power, the patterned MOR layer 118 exhibits break in some regions, indicating over etching. Upon power optimization to 250 W RF source power and 200 W RF bias power, the etched features maintain vertical profiles while eliminating MOR break issues, as evidenced by cross-sectional SEM images.

In various embodiments, SEM analysis demonstrates that the bias RF power helps achieve selective titanium etching. In one embodiment, the patterned MOR layer 118 comprises tin and the metal-containing layer 106 comprises titanium. The cross-sectional SEM images show effective pattern transfer when implementing a process using a gas mixture of 22 sccm SiCl₄ and 20 sccm CF₄ with 700 W RF source power and 400 W RF bias power. The etched features exhibit vertical sidewalls and complete titanium removal in exposed areas. However, when the 400 W bias power is eliminated while maintaining other parameters, no significant titanium etching occurs. Similarly, when SiCl₄ is removed from the gas mixture while maintaining CF₄ flow and RF powers, the titanium layer remains intact, indicating insufficient etch capability. These results demonstrate that both appropriate bias power and the presence of SiCl₄ are needed to achieve selective titanium etching in this process.

In various embodiments, the plasma 14 generated from the fluorocarbon/BCl₃ or fluorocarbon/SiCl₄ combinations may be implemented individually or in combination to achieve desired etch performance. The etch process may employ these combinations sequentially, where different gas combinations are used in successive process steps to optimize specific aspects of the etch profile. For example, one combination may be utilized for bulk titanium removal while another optimizes sidewall profile and selectivity. In one or more embodiments, the gas combinations may be mixed in varying ratios throughout the etch process to fine-tune etch characteristics. The process parameters including flow rates, RF power, and chamber pressure may be adjusted for each chemistry or combination to achieve optimal selective etching of titanium while maintaining MOR pattern integrity.

In various embodiments, FIG. 1F illustrates the substrate 100 after completing the selective plasma etch process of the metal-containing layer 106. In one or more embodiments, the plasma etch process may extend the openings 116 vertically through both the metal-containing layer 106, terminating at the top surface of the layer to-be-patterned 104. The selective nature of the etch chemistry described in FIG. 1E preserves the critical dimensions of the patterned MOR layer 118 while effectively removing exposed regions in the metal-containing layer 106 and form a patterned metal-containing layer 107. This ensures precise pattern transfer from the patterned MOR layer 118 to the patterned metal-containing layer 107. In some embodiments, the patterned MOR layer 118 and the patterned metal-containing layer 107 may serve as a hard mask 120 for subsequent processing steps.

In alternative embodiments illustrated in FIG. 2C, the plasma etch process illustrated in FIG. 1E may extend the openings 116 vertically through both the metal-containing layer 106 and the metal oxide layer 210, terminating at the top surface of the layer to-be-patterned 104. The etch process may transfer pattern in the patterned MOR layer 118 to the metal oxide layer 120 and form a patterned metal oxide layer 212. In some embodiments, the hard mask 120 may further comprise the patterned metal oxide layer 212.

In various embodiments, an optical monitoring system may be coupled to the process chamber to provide real-time feedback during the etch process. The optical monitoring system may comprise an Optical Emission Spectroscopy (OES) detector that analyzes the plasma emission spectrum to monitor the presence and concentration of specific chemical species within the plasma. The OES detector may track emission wavelengths characteristic of metal-containing species, enabling precise endpoint detection when the metal-containing layer 106 is sufficiently removed.

In one or more embodiments, the optical monitoring system may include additional components such as interferometers, ellipsometers, or reflectometers to measure etch depth and uniformity across the substrate surface. These optical measurements provide feedback for process control and help determine the completion of the metal-containing layer etching process. The optical monitoring system may utilize signal processing algorithms to analyze the optical data to detect an endpoint of the etch process. The integration of advanced optical monitoring enables precise control of the etch process, ensuring complete removal of metal-containing layers while preventing over-etching that could impact underlying materials or critical dimensions.

In various embodiments, FIG. 1G illustrates the continued process of the substrate 100 by using the hard mask 120 as an etch mask for etching a feature in the layer to-be-patterned 104. In one or more embodiments, the substrate 100 may be exposed to a plasma 16 generated by applying the RF power. The etch process may extend the openings 116 vertically through the layer to-be-patterned 104. Chemistries of the plasma 16 may be selected based on the composition of the layer to-be-patterned 104. In various embodiments, the plasma 16 may comprise argon, oxygen, nitrogen, hydrogen, fluorocarbon-based chemistry such as CF₄, C₄F₈, C₄F₆, chlorine-based or fluorine-based chemistries such as Cl₂, BCl₃, SF₆, or their combinations.

FIG. 1H illustrates the substrate 100 after completing the etch of the layer to-be-patterned 104. In one or more embodiments, the plasma etch process may extend the openings 116 vertically through the layer to-be-patterned 104, terminating at the top surface of the substrate layer 102. In various embodiments, the optical monitoring system may provide real-time feedback during the etch process. The endpoint detection through the optical monitoring system ensures complete etching of the layer to-be-patterned 104 while prevents over-etching that could impact the underlying substrate layer 102. In an alternative embodiment illustrated in FIG. 2D, the layer to-be-patterned 104 may be etched using the hard mask 120 comprising the patterned metal oxide layer 212 as the etch mask.

In various embodiments, intermediate processing steps may be performed between the process steps as illustrated in FIGS. 1A-1H and FIGS. 2A-2D. For example, after each plasma process, the process chamber may be evacuated to remove process gases, volatile byproducts, or particles. The evacuation of process chamber may be followed by purging with inert gases such as argon, helium, or nitrogen to further clean the chamber environment. In some embodiments, prior to initiating each new process step, gas flow stabilization periods may be implemented where process gases may be introduced and allowed to reach steady-state flow conditions. In various embodiments, RF matching network parameters may be pre-tuned based on the specific process requirements. Moreover, the pressure of process chamber may be stabilized at target values before plasma ignition. These stabilization steps may help ensure reproducible process conditions across multiple substrates.

In various embodiments, in-situ cleaning or surface preparation steps may be performed between process steps illustrated in FIGS. 1A-1H and FIGS. 1A-1D. In some embodiments, brief plasma treatments may be applied to the substrate 100 to remove potential residues, native oxides, or surface contamination. Additionally, wafer clamping, de-clamping, and electrostatic chuck charging or de-charging steps may be performed as needed. In various embodiments, the substrate 100 may undergo cooling or heating steps to achieve optimal temperatures for subsequent processes. Transfer steps between different process chambers or modules may include vacuum preservation protocols to prevent ambient exposure when necessary.

FIG. 3 illustrates a process flow for selectively etching a metal-containing layer through a patterned MOR layer, in accordance with an embodiment.

In various embodiments, the etch process may begin with a step 302 with forming the metal-containing layer 106 over the layer to-be-patterned 104 of the substrate 100, as shown in FIG. 1A. In one or more embodiments, the metal-containing layer 106 may comprise titanium. In some embodiments, the metal-containing layer 106 may be deposited using physical vapor deposition techniques. In some embodiments, the metal oxide layer 108 may form over the metal-containing layer 106 upon exposure to atmosphere.

In step 304, the MOR layer 110 may be formed over the metal-containing layer 106. In some embodiments, the MOR layer 110 may comprise tin-containing materials. The patterned MOR layer 118 may be formed through the lithography process as described in FIGS. 1B-1D.

In step 306, the substrate 100 may transferred to the process chamber for plasma etching, as illustrated in FIG. 1E. In various embodiments, the processing chamber may be pre-conditioned through cleaning and seasoning steps to ensure process stability. The substrate temperature may be stabilized between 10° C. and 90° C. using electrostatic chuck temperature control systems. In some embodiments, the pressure of processing chamber may be established between 10 mTorr and 300 mTorr.

In step 308, the gas mixture comprising fluorocarbon and SiCl₄ may be flowed into the process chamber. The conditions of the gas mixture may follow the description of the gas mixture with reference to FIG. 1E. Additional process gases such as nitrogen or argon may be incorporated to enhance plasma characteristics. Gas flows may be stabilized before plasma ignition to ensure uniform distribution.

In step 310, a plasma may be generated from the gas mixture by applying an RF power, with power levels ranging from 150 W to 1500 W. The RF matching network may be optimized to ensure efficient power transfer to the plasma. In various embodiments, multiple RF power sources may be utilized to independently control ion energy and plasma density.

In step 312, corresponding to FIGS. 1E and 1F, the substrate 100 may be exposed to the plasma to selectively etch the metal-containing layer 106 and form the patterned metal-containing layer 107. The selective nature of the fluorocarbon/SiCl₄-based plasma chemistry enables precise pattern transfer while preserving the MOR layer integrity. The process may be monitored using optical endpoint detection systems to ensure complete removal of metal-containing layers in the exposed areas.

In step 314, the patterned MOR layer 118 and the patterned metal-containing layer 107 may serve as the hard mask 120. The hard mask 120 may be used as the etch mask to etch a feature in the underlying layer to-be-patterned 104 as illustrated in FIGS. 1G and 1H.

In various embodiments, FIG. 4 illustrate alternative process flows for selective etching of the metal-containing layer 106 using different plasma chemistries. The initial steps 402-406 may be parallel those described in FIG. 3 (steps 302-306), including metal-containing layer formation, MOR layer patterning, and substrate transfer to the process chamber.

FIG. 4 illustrates a process variation utilizing the gas mixture comprising fluorocarbon and BCl₃ at step 408. The flow rates of the gas mixture may follow the descriptions about the gas mixture in FIG. 1E. Steps 410-414 may proceed with plasma generation and selective etching under similar RF power and chamber conditions as previously described in FIG. 3 (steps 310-314), while leveraging the unique properties of the fluorocarbon/BCl₃ combination as described with reference to FIG. 1E.

In various embodiments, each of chemical combinations described in FIGS. 3 and 4 provides selective titanium etching capabilities through different reaction pathways as described above with reference to FIGS. 5A and 5B. These combinations may offer high process flexibility in selecting optimal chemistry based on specific integration requirements and equipment configurations. In various embodiments, the process flows may include additional steps not explicitly shown in FIGS. 3 and 4, such as chamber preparation, gas evacuation, pressure stabilization, and temperature control steps between the illustrated steps in FIGS. 3 and 4.

In various embodiments, while FIGS. 3 and 4 illustrate distinct process flows using different etch chemistries, these approaches may be combined or sequentially implemented to optimize etch performance. In some embodiments, the gas chemistries described in steps 308 (fluorocarbon/SiCl₄) and 408 (fluorocarbon/BCl₃) may be utilized in various combinations within a single etch process. For example, an initial etch step may employ fluorocarbon/SiCl₄ chemistry to initiate titanium removal, followed by fluorocarbon/BCl₃ chemistry to optimize sidewall profiles, and concluding with fluorocarbon/SiCl₄ chemistry for final profile refinement.

In one or more embodiments, the transition between different chemical combinations may be implemented through gradual gas flow adjustments or discrete process steps. Process parameters including RF power, chamber pressure, and substrate temperature may be independently optimized for each chemistry combination. The sequential or combined application of multiple etch chemistries enables fine-tuning of etch profiles, selectivity, and critical dimension control throughout the pattern transfer process. Real-time monitoring using the optical monitoring system may guide the transition timing between different chemical combinations.

FIG. 6 shows an example processing system 600 for etching a substrate as described in the methods with reference to FIGS. 1A-4, in accordance with various embodiments.

For illustrative purposes, FIG. 6 illustrates the substrate 100 placed on a substrate holder 610 (e.g., a circular electrostatic chuck (ESC)) inside a process chamber 620 near the bottom. The substrate 100 may be optionally maintained at a desired temperature using a heater/cooler 615 that surrounds the substrate holder 610. The temperature of the substrate 100 may be regulated by a temperature controller 630 connected to the substrate holder 610 and the heater/cooler 615. The ESC may be coated with a conductive material (e.g., a carbon-based or metal-nitride based coating) so that electrical connections may be made to the substrate holder 610.

In various embodiments, the temperature controller 630 may receive temperature feedback signals from one or more temperature sensors associated with the substrate holder 610 or substrate 100. In an embodiment, the temperature controller 630 may comprise a closed-loop control system that adjusts power to the heater/cooler 615 based on the temperature feedback signals to maintain the substrate 100 at the desired temperature or within a target temperature range. In one or more embodiments, the temperature controller 630 may comprise a processor, a memory storing temperature control algorithms, and input/output interfaces for communicating with the temperature sensors and the heater/cooler 615. The temperature controller 630 may adjust heating or cooling power in real-time during plasma processing to compensate for thermal effects from the plasma and maintain stable substrate temperature.

Gases used during etch process may be introduced into the process chamber 620 by gas delivery systems 670. The gas delivery systems 670 may comprise a plurality of gas flow controllers to control the flow of a gas mixture into the process chamber. Each of the gas flow controllers of the gas delivery systems 670 may be assigned for each of fluorocarbons, silicon tetrachloride, boron trichloride, noble gases, and/or balancing agents. In some embodiments, optional center/edge splitters may be used to independently adjust the gas flow rates at the center and edge of the substrate 100. The process gases or any exhaust gases may be evacuated from the process chamber 620 using vacuum pumps 680.

In various embodiments, the substrate holder 610 may be a bottom electrode of the process chamber 620. In the illustrative example in FIG. 6, the substrate holder 610 may be connected to a RF power source 642, which may be configured to apply a bias power or low frequency power to control plasma reaction with the substrate 100. In some embodiment, a conductive circular plate inside the process chamber 620 near the top may be the top electrode 650. The top electrode 650 may be connected to another RF power source 644 which may be configured to apply a source power or a high frequency power to generate and sustain the plasma (e.g., the plasma 14 and 16) in the process chamber 620. In various embodiments, the RF power sources 642 and 644 may be connected to a control unit 655 to enable a synchronized or unsynchronized operation of the power sources.

In some embodiments, the control unit 655 may be coupled to an optical monitoring system 645, and configured to monitor the etching process and perform endpoint detection. In various embodiments, the optical monitoring system 645 may comprise optical sensors for measuring plasma emission characteristics within the process chamber 620. The optical monitoring system 645 may comprise a photodetector array, such as a charge-coupled device (CCD) sensor, complementary metal-oxide-semiconductor (CMOS) sensor, or photodiode array, positioned to receive optical emissions through a viewport or window of the process chamber 620. In an embodiment, the optical monitoring system 645 may include collection optics such as fiber optic cables, lenses, mirrors, and/or collimators to gather and direct the optical emissions to the photodetector array. A spectral filter or diffraction grating may be positioned between the collection optics and the photodetector array to separate the optical emissions into different wavelength components. The optical monitoring system 645 may further comprise analog-to-digital converters to convert the detected optical signals into digital data, and a processor configured to analyze spectral intensities at selected wavelengths. In one or more embodiments, the optical monitoring system 645 may monitor real-time changes in plasma emission spectra to detect process endpoints or abnormal process conditions. The processor executes algorithms stored in memory to compare measured spectral data against reference spectra and generate control signals for modifying process parameters based on the spectral analysis. In various embodiments, the optical monitoring system 645 may further comprise the components, algorithms, and functions of the corresponding optical monitoring system as described with reference to FIG. 1F.

In some embodiments, the control unit 655 may also be coupled to the gas delivery system 670. In various embodiments, the control unit 655 may manage individual gas flow controllers within each gas delivery system 670 to precisely regulate gas flow rates, composition ratios, and timing sequences. In one or more embodiments, the control unit 655 dynamically adjusts gas flows through different ports to maintain optimal gas distribution patterns across the substrate 100 surface.

In various embodiments, the control unit 655 may be configured to enable feedback control of a plasma process, for example, based on the process monitoring using the optical monitoring system 645. In one or more embodiments, the control unit 655 may comprise a function generator including an appropriate digital and/or analog circuitry such as oscillators, pulse generators, modulators, combiners, and the like. The function generator may be capable of generating one or more arbitrary waveforms that may be used for both power modulation of the RF power sources and optical data acquisition. In certain embodiments, some of the power modulation may be performed by the RF power sources themselves instead of the function generator. In such cases, the function generator may generate a pulse train synchronized with the power modulation by the RF power sources for optical data acquisition. In certain embodiments, although not illustrated, additional components (e.g., a broadband amplifier and a broadband impedance matching network) may be connected to the RF power sources.

In certain embodiments, the illustrated power sources (e.g., the RF power sources 642 and 644) may be DC power sources. The RF and/or DC power sources may be configured to generate a continuous wave (CW) RF, pulsed RF, DC, pulsed DC, a high frequency rectangular (e.g., square wave) or triangular (e.g., sawtooth) pulse train, or a combination or superposition of more than one such waveform. In addition, power sources may be configured to generate a periodic function, for example, a sinusoid whose characteristics such as amplitude and frequency may be adjusted during a plasma process.

A typical frequency for the RF source power can range from about 0.1 MHz to about 6 GHz. In certain embodiments, the RF power sources 642 and 644 may be used to provide a low frequency RF power and a high frequency RF power at the same time, respectively.

In certain embodiments, the plasma etch process may be carried out using a pulsed plasma. The pulsed plasma in this disclosure refers to any type of plasma where a source power, a bias power, or both is pulsed at any frequency. In various embodiments, a pulsing at a frequency between 0.1 kHz and 100 kHz may be used to modulate the plasma source power or the bias power. In certain embodiments, a RF pulsing at a kHz range may be used to power the plasma. In various embodiments, any duty ratio (e.g., 0.1% to 99.9%) may be used for any plasma tool. In certain embodiments, a moderate duty ratio between 10% to 70% or 10% to 80% may be used for capacitively coupled plasma (CCP), and 3% to 90% for inductively coupled plasma (ICP). In one embodiment, a sinusoidal RF signal of 1 MHz may be modulated with an on-off frequency of 100 Hz. In another embodiment, a DC signal may be modulated with an on-off frequency of 100 Hz. In yet another embodiment, a square DC pulse signal of 1 MHz may be modulated with an on-off frequency of 100 Hz. In an alternate embodiment, cyclic modulation of RF or fast DC pulse waveform may be performed at a lower frequency (e.g., <100 Hz) using an algorithm.

In some embodiments, the processing system 600 may be a capacitively coupled plasma (CCP) system, as illustrated in FIG. 6, or an inductively coupled plasma (ICP) plasma system. In alternate embodiments, the processing system 600 may comprise a resonator such as a helical resonator. Further, microwave plasma (MW) or other suitable systems may also be used. In various embodiments, the RF power, chamber pressure, substrate temperature, gas flow rates and other plasma process parameters may be selected in accordance with the respective process recipe.

Example embodiments of the invention are described below. Other embodiments can also be understood from the entirety of the specification as well as the claims filed herein.
Example 1. A method for etching a substrate, the method including: transferring a substrate into a process chamber, the substrate including a metal-containing layer disposed over a layer to-be-patterned, and a patterned metal oxide resist layer disposed over the metal-containing layer; flowing a gas mixture including fluorocarbon and SiCl₄ into the process chamber; generating a plasma from the gas mixture in the process chamber by applying a RF power; and exposing the substrate to the plasma and transferring a pattern of the patterned metal oxide resist layer to the metal-containing layer to form a patterned metal-containing layer.
Example 2. The method of example 1, further including etching a feature in the layer to-be-patterned using the patterned metal oxide resist layer and the patterned metal-containing layer as an etch mask.
Example 3. The method of one of examples 1 or 2, where the layer to-be-patterned includes silicon or carbon.
Example 4. The method of one of examples 1 to 3, where the patterned metal oxide resist layer includes tin.
Example 5. The method of one of examples 1 to 4, where the metal-containing layer includes titanium.
Example 6. The method of one of examples 1 to 5, where a flow rate ratio of fluorocarbon to SiCl₄ is between 1:4 and 4:1.
Example 7. The method of one of examples 1 to 6, where a sum of flow rates of fluorocarbon and SiCl₄ is between 10 sccm and 250 sccm.
Example 8. The method of one of examples 1 to 7, where the fluorocarbon includes CF₄ or C₄F₆.
Example 9. The method of one of examples 1 to 8, further including: while applying the RF power, applying a RF bias power to a substrate holder that holds the substrate.
Example 10. A method for etching a substrate, the method including: after loading the substrate into a process chamber, flowing a gas mixture including fluorocarbon and BCl₃ into the process chamber, the substrate including a metal-containing layer disposed over a layer to-be-patterned, and a patterned metal oxide resist layer disposed over the metal-containing layer; generating a plasma in the process chamber from the gas mixture in the process chamber by applying a RF power to an electrode of the process chamber; and exposing the substrate to the plasma to transfer a pattern of the patterned metal oxide resist layer to the metal-containing layer.
Example 11. The method of example 10, further including transferring the pattern of the patterned metal oxide resist layer to the layer to-be-patterned through the metal-containing layer.
Example 12. The method of one of examples 10 or 11, where the patterned metal oxide resist layer includes tin.
Example 13. The method of one of examples 10 to 12, where the metal-containing layer includes titanium.
Example 14. The method of one of examples 10 to 13, where a flow rate ratio of fluorocarbon to BCl₃ is between 1:4 and 4:1.
Example 15. The method of one of examples 10 to 14, where a sum of flow rates of fluorocarbon and BCl₃ is between 10 sccm and 250 sccm.
Example 16. The method of one of examples 10 to 15, where the fluorocarbon includes CF₄ or C₄F₆.
Example 17. The method of one of examples 10 to 16, further including: while applying the RF power, applying a RF bias power to a substrate holder that holds the substrate.
Example 18. A method for etching a substrate, the method including: loading a substrate into a process chamber, the substrate including a metal oxide resist layer disposed over a metal-containing layer, the metal-containing layer is disposed over a layer to-be-patterned; etching a pattern through the metal oxide resist layer to form a patterned metal oxide resist layer; flowing a gas mixture including CF₄ and SiCl₄, or CF₄ and BCl₃, or C₄F₆ and SiCl₄ into the process chamber; generating a plasma from the gas mixture in the process chamber; and transferring the pattern of the patterned metal oxide resist layer to the metal-containing layer and the layer to-be-patterned.
Example 19. The method of example 18, where the metal oxide resist layer includes tin.
Example 20. The method of one of examples 18 or 19, where the metal-containing layer includes titanium.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-1H, 2A-2D, 3, 4, and 6 may be combined in further embodiments. It is therefore intended that the appended claims encompass any such modifications or embodiments.

What is claimed is:

1. A method for etching a substrate, the method comprising:
transferring a substrate into a process chamber, the substrate comprising a metal-containing layer disposed over a layer to-be-patterned, and a patterned metal oxide resist layer disposed over the metal-containing layer;
flowing a gas mixture comprising fluorocarbon and SiCl₄ into the process chamber;
generating a plasma from the gas mixture in the process chamber by applying a RF power; and
exposing the substrate to the plasma and transferring a pattern of the patterned metal oxide resist layer to the metal-containing layer to form a patterned metal-containing layer.

2. The method of claim 1, further comprising etching a feature in the layer to-be-patterned using the patterned metal oxide resist layer and the patterned metal-containing layer as an etch mask.

3. The method of claim 1, wherein the layer to-be-patterned comprises silicon or carbon.

4. The method of claim 1, wherein the patterned metal oxide resist layer comprises tin.

5. The method of claim 1, wherein the metal-containing layer comprises titanium.

6. The method of claim 1, wherein a flow rate ratio of fluorocarbon to SiCl₄ is between 1:4 and 4:1.

7. The method of claim 1, wherein a sum of flow rates of fluorocarbon and SiCl₄ is between 10 sccm and 250 sccm.

8. The method of claim 1, wherein the fluorocarbon comprises CF₄ or C₄F₆.

9. The method of claim 1, further comprising:
while applying the RF power, applying a RF bias power to a substrate holder that holds the substrate.

10. A method for etching a substrate, the method comprising:
after loading the substrate into a process chamber, flowing a gas mixture comprising fluorocarbon and BCl₃ into the process chamber, the substrate comprising a metal-containing layer disposed over a layer to-be-patterned, and a patterned metal oxide resist layer disposed over the metal-containing layer;
generating a plasma in the process chamber from the gas mixture in the process chamber by applying a RF power to an electrode of the process chamber; and
exposing the substrate to the plasma to transfer a pattern of the patterned metal oxide resist layer to the metal-containing layer.

11. The method of claim 10, further comprising transferring the pattern of the patterned metal oxide resist layer to the layer to-be-patterned through the metal-containing layer.

12. The method of claim 10, wherein the patterned metal oxide resist layer comprises tin.

13. The method of claim 10, wherein the metal-containing layer comprises titanium.

14. The method of claim 10, wherein a flow rate ratio of fluorocarbon to BCl₃ is between 1:4 and 4:1.

15. The method of claim 10, wherein a sum of flow rates of fluorocarbon and BCl₃ is between 10 sccm and 250 sccm.

16. The method of claim 10, wherein the fluorocarbon comprises CF₄ or C₄F₆.

17. The method of claim 10, further comprising:
while applying the RF power, applying a RF bias power to a substrate holder that holds the substrate.

18. A method for etching a substrate, the method comprising:
loading a substrate into a process chamber, the substrate comprising a metal oxide resist layer disposed over a metal-containing layer, the metal-containing layer is disposed over a layer to-be-patterned;
etching a pattern through the metal oxide resist layer to form a patterned metal oxide resist layer;
flowing a gas mixture comprising CF₄ and SiCl₄, or CF₄ and BCl₃, or C₄F₆ and SiCl₄ into the process chamber;
generating a plasma from the gas mixture in the process chamber; and
transferring the pattern of the patterned metal oxide resist layer to the metal-containing layer and the layer to-be-patterned.

19. The method of claim 18, wherein the metal oxide resist layer comprises tin.

20. The method of claim 18, wherein the metal-containing layer comprises titanium.
